(19) United States
(12) Patent Application Publication
(10) Pub. No.: US 2025/0046729 A1
(43) Pub. Date: Feb. 6, 2025

(54) SEMICONDUCTOR DEVICES AND FABRICATION METHODS THEREOF, MEMORY SYSTEMS

(71) Applicant: Yangtze Memory Technologies Co., Ltd., Wuhan (CN)

(72) Inventor: Hong Fang, Wuhan (CN)

(21) Appl. No.: 18/528,261

(22) Filed: Dec. 4, 2023

(30) Foreign Application Priority Data
Jul. 31, 2023 (CN) 202310957226.X

(51) Int. Cl. H01L 23/544; H01L 23/00

(52) U.S. Cl. CPC H01L 23/544; H01L 23/562; H01L 2223/5446

(57) ABSTRACT

Implementations of the present application disclose a semiconductor device and a fabrication method thereof, and a memory system. The fabrication method includes: forming a semiconductor structure in the wafer, including forming a first device and a first scribe line abutting the first device in a first direction and extending in a second direction, the first direction intersecting the second direction; forming a barrier structure extending in the second direction at a site in the first scribe line abutting the first device. The present application reduces the probability of scribe line cracks, increase productions of chips and reduce costs of fabrication.

### REFERENCE TO RELATED APPLICATIONS

This application claims priority to and the benefit of Chinese Patent Application 202310957226.X, filed on Jul. 31, 2023, which is hereby incorporated by reference in its entirety.

### TECHNICAL FIELD

The present application is related to the semiconductor technology field, in particular to a semiconductor device and a fabrication method thereof, as well as a memory system.

### BACKGROUND

Wafers are the fundamental raw material for manufacturing semiconductor devices. Each wafer may be cut into a plurality of wafer pieces. Each wafer piece can be made into a chip after processes and flows such as packaging, testing.

### BRIEF DESCRIPTION OF DRAWINGS

In order to explain technical solutions in implementations of the present application more clearly, accompanying drawings required in describing implementations will be described in brief below. It is obvious that drawings in the description below are only some implementations of the present application and other drawings may be obtained according to these drawings without any creative work.

FIG. 1 is a flowchart illustrating a fabrication method of a semiconductor device provided by an implementation of the present application;

FIGS. 2-3 are structure diagrams during the fabrication process of a semiconductor device provided by some implementations of the present application;

FIG. 4 is a structure diagram of a barrier structure provided in an implementation of the present application;

FIG. 5 is an enlarged diagram of a barrier structure with grooves provided in an implementation of the present application;

FIG. 6 is a structure diagram of a first device and a barrier structure provided in an implementation of the present application;

FIG. 7 is another flowchart illustrating a fabrication method of a semiconductor device provided by an implementation of the present application;

FIG. 8 is another flowchart illustrating a fabrication method of a semiconductor device provided by an implementation of the present application;

FIG. 9 is a graph diagram of the scribe line size vs the number of effective devices provided in implementations of the present application;

FIG. 10 is another graph diagram of the scribe line size vs the number of effective devices provided in implementations of the present application;

FIG. 11 is another graph diagram of the scribe line size vs the number of effective devices provided in implementations of the present application; and

FIG. 12 is a structure diagram of a memory system provided in an implementation of the present application.

### DETAILED DESCRIPTION

The technical solutions in implementations of the present application will be described clearly and fully below in connection with accompanying drawings in implementations of the present application. Obviously, the described implementations are only a part of implementations of the present application rather than all of them. Based on the implementations of the present application, all other implementations obtained by those skilled in the art without any creative work fall within the scope of the present application.

In the description of the present application, it is appreciated that the terms “first”, “second” etc. are only used for the purpose of description and should not be understood to indicate or imply relative importance or to designate the number of the referenced technical features implicitly. Therefore, features defined with “first” and “second” may explicitly or implicitly include one or more said features. In the description of the present application, “a plurality of” means two or more unless otherwise specified.

In the description of the present application, unless being specified or defined expressly otherwise, it is to be noted that the terms “mount”, “interconnect” and “connect” should be explained broadly, they include, for example, fixed connection, removable connection or integral connection; mechanical connection, electrical connection or mutual communication; direct interconnection or interconnection indirectly with intermediate medium; or inner communication or interaction between two elements. The specific meaning of the above-mentioned terms in the present application will be understood by those of ordinary skill in the art depending on specific circumstances.

In the description of the present application, unless being specified or defined expressly otherwise, when a first feature is referred to as being “over” or “under” a second feature, the first feature may be in direct contact with the second feature, or the first feature may be in contact with the second feature indirectly through any other features therebetween. Moreover, a first feature being “over”, “above” or “on” a second feature includes the first feature being directly or obliquely above the second feature, or only means that the first feature has a level higher than the second feature. The first feature being “under”, “below” and “beneath” the second feature includes the first feature being directly or obliquely under the second feature or only means that the first feature has a horizontal height smaller the second feature.

It is to be noted that the views provided in the implementations of the present application are only used to illustrate the basic conception of the present application schematically, and the figures only show components related in the present application, but not depicted according to the numbers, shapes and dimensions of components in practice. In practical implementation, the configuration, number and scale of components may be varied arbitrarily and the layout of the components may be more complicated.

In the chip manufacturing process, separate dies are obtained by cutting between adjacent wafer pieces on a wafer, and separate chips are obtained after flows such as packaging and testing. However, as the area of an individual chip decreases, the chip manufacturing process needs improvements.

Before cutting each wafer, it is required to determine a maximum number of complete chips that can be cut from the wafer to increase production of chips and reduce costs of manufacturing. In the chip manufacturing process, scribe lines are formed between adjacent two chips on the wafer such that separate dies are obtained by cutting between wafers along scribe lines, and separate chips are obtained after flows such as packaging and testing. TSKs (Test-Key) and process marks (MASK) of all electrical characteristics are provided in the scribe lines for measuring and locating the wafer. However, as the area of individual chips decreases, density of chips on the wafer increases accordingly. Then area loss caused by the scribe lines becomes more and more significant. Therefore, reducing the area occupied by the scribe lines can increase the number of effective chips that can be cut from the wafer. However, since the scribe line is of a strip shape, stress resulted from wafer cutting will inevitably concentrate in the scribe line, resulting in cracks in the scribe line.

In implementations of the present application, there is an angle between a first direction and a second direction that is less than or equal to 90 degrees. For example, in some implementations of the present application, the first direction is set as Y direction, and the second direction is set as X direction.

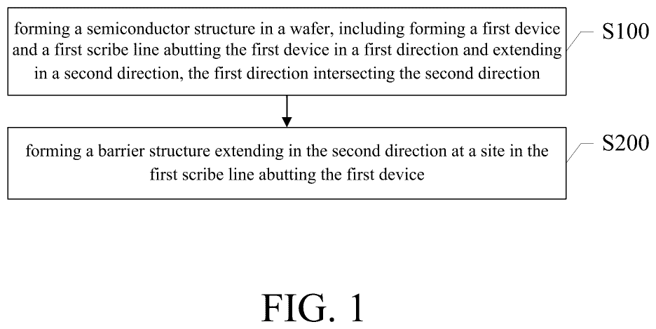

In order to improve the above-described problem, referring to FIGS. 1-7, some implementations of the present application provide a semiconductor device 100 and a fabrication method thereof, as well as a memory system 300. In the present application, barrier structures 20 disposed at intervals are formed between adjacent first devices 10 in the first direction Y by utilizing the existing empty spaces in the first scribe line 31, such that it is possible to prevent cracks occurring in the first scribe line 31 from diffusing or extending to the first device 10, thereby effectively blocking extension of cracks, improving yields and reliability of effective chips, thus improving production of chips and reducing costs of fabrication.

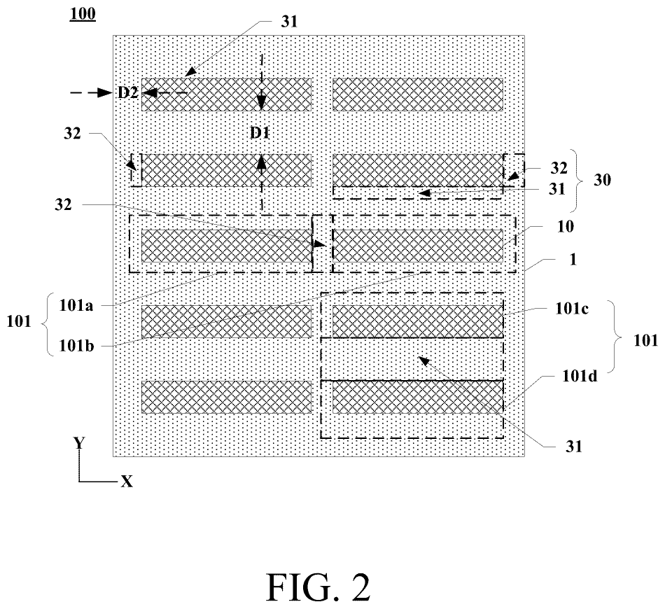

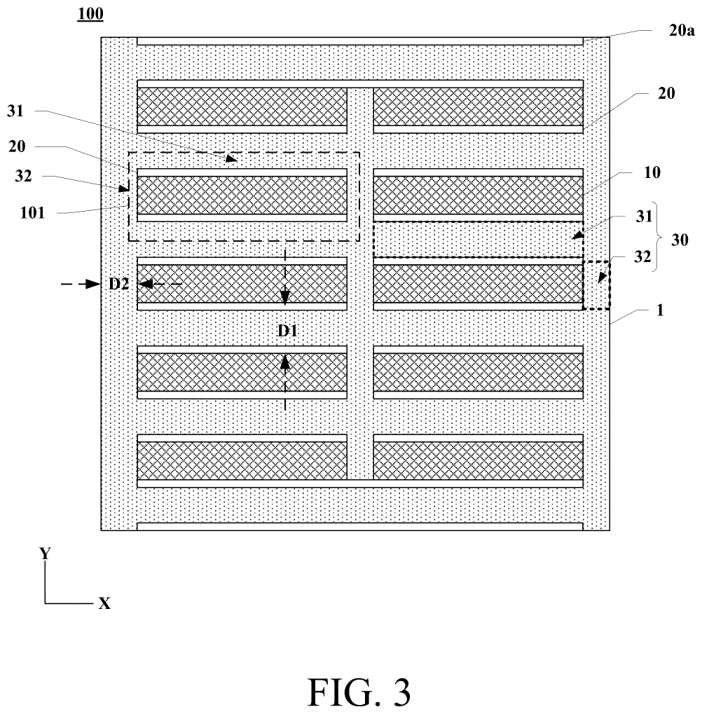

Referring to FIGS. 1-3. FIG. 1 is a flowchart illustrating a fabrication method of a semiconductor device 100 provided by some implementations of the present application, and FIGS. 2-3 are structure diagrams during the fabrication process of the semiconductor device 100 provided by some implementations of the present application. As shown in FIG. 1, the fabrication method includes the following operations:

S100, forming a semiconductor structure 101 in a wafer 1, including forming a first device 10 and a first scribe line 31 abutting the first device 10 in a first direction Y and extending in a second direction X, the first direction Y intersecting the second direction X;

S200, forming a barrier structure 20 extending in the second direction X at a site in the first scribe line 31 abutting the first device 10.

In some specific examples, as shown in FIGS. 2 and 3, the semiconductor device 100 includes the wafer 1 and a semiconductor structure array, first scribe lines 31 and barrier structures 20 on the wafer 1. As shown in FIG. 2, semiconductor device arrays are formed on the wafer 1 and each semiconductor device array includes a plurality of semiconductor structures 101 arranged in an array. Each of the semiconductor structures 101 includes the first device 10 and at least one first scribe line 31. The first scribe line 31 abuts the first device 10 in the first direction Y, that is, the first device 10 is adjacent to and contacts the at least one first scribe line 31 in the first direction Y. In addition, each first scribe line 31 extends in the second direction X.

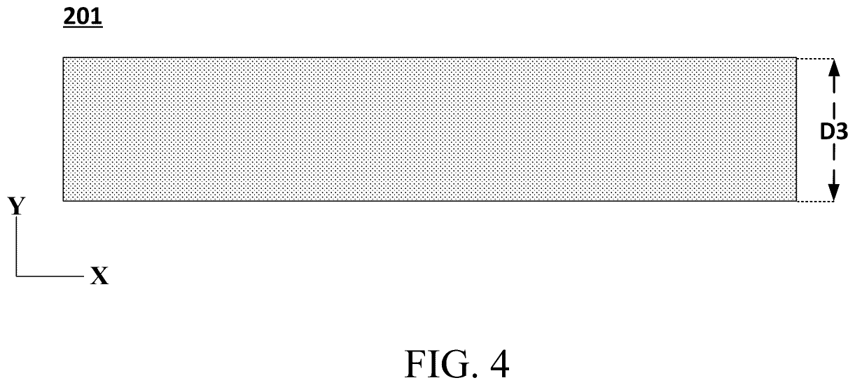

In some specific examples, the barrier structure 20 extending in the second direction X is formed in the first scribe line 31. As shown in FIG. 3, each semiconductor structure 101 further includes at least one barrier structure 20 extending in the second direction X that is located in the first scribe line 31 and abutting the first device 10 in the first direction Y. The barrier structure 20 shown in FIG. 4 is an enlarged diagram of the barrier structure 20 in FIG. 3.

In implementations of the present application, the plurality of first device 10 arranged in an array are formed on the wafer 1 firstly. Then parts of the wafer 1 that abut the first devices 10 in the first direction Y are removed by dry etching process to form the first scribe lines 31 abutting the first devices 10 in the first direction Y. Subsequently, a dielectric material is deposited in the first scribe lines 31 to form the barrier structures 20a abutting the plurality of first devices 10 in the first direction Y.

In some implementations, the dielectric material includes any one of poly-crystalline silicon, silicon nitride, silicon oxide, aluminum oxide or any combination thereof.

In some implementations, the way of deposition may include chemical vapor deposition (CVD), physical vapor deposition (PVD), Plasma-enhanced CVD (PECVD), sputtering, Metal-organic chemical vapor deposition (MOCVD) and atomic layer deposition (ALD) etc.

In some implementations, since stresses suffered when cutting along the first scribe line 31 between adjacent semiconductor structures 101 are different, cracks tend to form upon cutting and extend to the first device 10 adjacent to the first scribe line 31. Therefore, in the present application, the barrier structure 20a abutting a plurality of first devices 10 in the first direction Y is broken. The barrier structure 20a shown in FIG. 3 is etched in the second direction to form a plurality of barrier structures 20. The plurality of barrier structures 20 each of which abutting one first device 10 in the first direction Y and having an extension size in the second direction X. The extension size greater than or equal to an extension size of the first device 10 abutted by the barrier structure 20 in the second direction X.

In some specific examples, forming the barrier structures 20 arranged at intervals between adjacent first devices 10 in the first direction Y by utilizing existing empty spaces of the first scribe line 31 does not need to enlarge the size of the first scribe line 31 to form the barrier structures 20. Since the area occupied by the first scribe line 31 is not increased, as compared to the way that increasing the size of the first scribe line 31 to prevent cracks generated upon cutting from extending to the first device 10, it is possible to increase the production of chips and reduce cost of fabrication without reducing the density of first device 10 on the wafer 1. In addition, in the present application, the barrier structure 20 is disposed at a site abutting the first device 10 in the first direction Y, and since the barrier structure 20 is located between the first scribe line 31 and the first device 10 in the first direction Y, it is possible to use the barrier structure 20 to prevent cracks in the first scribe line 31 from diffusing or extending to the first device 10, thereby effectively blocking extension of the cracks, reducing the number of the first devices 10 that are damaged due to diffusion of the cracks, thus increasing the number of separated and undamaged first devices 10 that are obtained by cutting, and increasing the yield and reliability of effective chips.

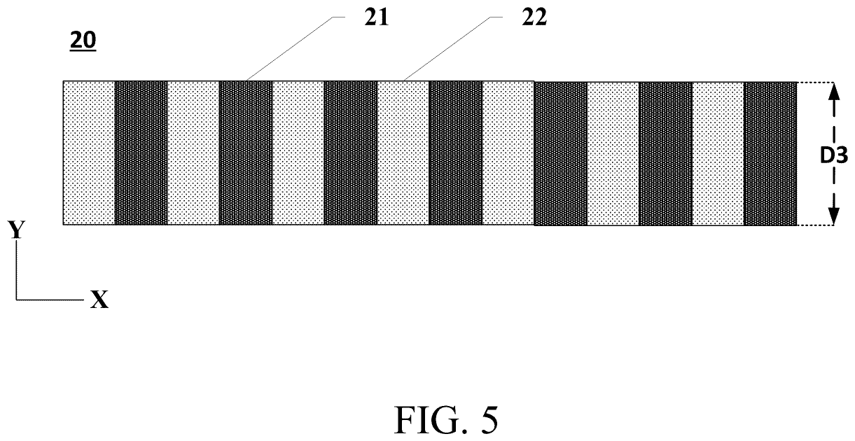

In some implementations, said forming barrier structures 20 extending in the second direction X further includes: as shown in FIGS. 4 and 5, forming a plurality of ring shape structures 201 extending in the second direction X in the first scribe line 31; and forming a plurality of grooves 21 arranged at intervals in the second direction X in the ring shape structure 201, the grooves 21 extending in the first direction Y.

In some specific examples, a dielectric material is deposited in the first scribe line 31 as shown in FIG. 2 to form the ring shape structure 201 as shown in FIG. 4, then parts of the ring shape structure 201 are removed to form the plurality of grooves 21 arranged at intervals in the second direction X and extending in the first direction Y as shown in FIG. 5. Before forming the plurality of grooves 21 as shown in FIG. 5, a patterned first mask layer (not shown) is formed on a surface of the barrier structure 20 in the second direction X, the first mask layer having a plurality of openings (not shown) for forming the plurality of grooves 21. Thus, openings corresponding to the plurality of grooves 21 may be formed in the patterned first mask layer to expose locations of the plurality of grooves 21 to be formed by subsequent etching process, that is, vertical projections of the openings on the surface of the barrier structure 20 in the second direction X may at least overlap substantially with the locations of the plurality of grooves 21. Then, the locations of the barrier structure 20 corresponding to the openings of the first mask layer may be etched with photolithography (PH) or dry etching (ET) to remove parts of the barrier structure 20 that are under the openings to form the plurality of grooves 21. Therefore, in implementations of the present application, by disposing the first mask layer, it is possible to determine the etching locations of the plurality of grooves 21 quickly and accurately, which facilitates the etching process to the barrier structure 20 and in turn forms the plurality of grooves 21 arranged at intervals in the second direction X and extending in the first direction Y in the barrier structure 20.

It is to be noted that the plurality of grooves 21 can be formed on the barrier structure 20 at the same time, that is, the plurality of openings corresponding to the plurality of grooves 21 may be formed in the first mask layer and the locations of the plurality of openings correspond to the locations of the plurality of grooves 21 to be formed subsequently. The number, size and arrangement of the plurality of grooves 21 are not specifically limited in implementations of the present application. That is, the plurality of grooves 21 shown in FIG. 5 are only examples and not intended to limit the locations and number of the plurality of grooves 21.

In some specific examples, in some implementations, the etching size of a groove 21 in the first direction Y may be controlled by process parameters of etching (for example, etching duration, gas flow rate, ratio, pressure, temperature etc.). For example, given a constant etching rate, the longer the etching duration is, the deeper the formed groove 21 is in the first direction Y. The parts in the barrier structure 20 are removed to form the plurality of grooves 21 by etching along the first direction Y through the plurality of openings in the first mask layer that correspond to the plurality of grooves 21, and the plurality of grooves 21 formed by etching along the first direction Y do not expose the abutting first device 10. The way of etching may be dry or wet etch, e.g., electron beam photolithography process, plasma etch process or reactive ion etch process.

In implementations of the present application, the plurality of grooves 21 formed as shown in FIG. 5 are arranged at intervals in the second direction X, and partition structures 22 for separating adjacent two grooves 21 are provided between the plurality of grooves 21 formed in the barrier structure 20. Thus, in the present application, by designing an otherwise strip shape barrier structure 20 as the plurality of grooves 21 arranged at intervals in the second direction X, i.e., the plurality of grooves 21 and the partition structures 22 arranged alternatively in the second direction X, since the plurality of grooves 21 and the partition structures 22 are arranged alternatively, it is possible to reduce the degree of concentrated released stress while stress mismatch occurs in the first scribe line 31 and effectively release stress through the plurality of grooves 21 and nearby partition structures 22. In this way, it is possible to mitigate influence on the first scribe line 31 by the stress release and prevent the first scribe line 31 from deforming, thereby making the first scribe line 31 not prone to cracks, which may in turn prevent cracks occurring in the first scribe line 31 from diffusing or extending to the first device 10 abutting the first scribe line 31, hence effectively blocking extension of cracks and improving yield and reliability of chips.

In some examples, one semiconductor structure 101 may include the first device 10, and at least one first scribe line 31 and at least one second scribe line 32. If the semiconductor structure 101 is located at the boundary or edge of the wafer 1, the semiconductor structure 101 may include the first device 10, and one first scribe line 31 and one second scribe line 32. Of course, as shown in FIGS. 2 and 3, if the semiconductor structure 101 is located at the middle region, i.e. not at the edge of the wafer 1, the semiconductor structure 101 may include the first device 10, and two first scribe lines 31 and two second scribe lines 32. Two semiconductor structures 101 adjacent in the first direction Y may share one first scribe line 31. As shown in FIG. 2, a semiconductor structure 101c and a semiconductor structure 101d adjacent to the semiconductor structure 101c in the first direction Y may share a same first scribe line 31. Similarly, two semiconductor structures 101 adjacent in the second direction X may share a same second scribe line 32. As shown in FIG. 2, a semiconductor structure 101a and a semiconductor structure 101b adjacent to the semiconductor structure 101a in the second direction X may share one second scribe line 32.

In some implementations, forming the semiconductor structure 101 includes: forming the second scribe lines 32 abutting the first device 10 in the second direction X and extending in the first direction Y, and the size of the first scribe line 31 in the first direction Y is greater than the size of the second scribe line 32 in the second direction X.

In some specific examples, in implementations of the present application, a plurality of first devices 10 arranged in an array are formed on the wafer 1 firstly. Then parts of the wafer 1 that abut the first devices 10 in the first direction Y are removed by dry etching process to form first scribe lines 31 abutting the first devices 10 in the first direction Y. Subsequently, a dielectric material is deposited in the first scribe lines 31 to form barrier structures 20a abutting the plurality of first devices 10 in the first direction Y. As shown in FIGS. 2 and 3, second scribe lines 32 abutting the first devices 10 in the second direction X and extending in the first direction Y may also be formed on the wafer 1. Each of the semiconductor device array includes a plurality of semiconductor structures 101 arranged in an array. Each of the semiconductor structures 101 includes the first device 10, at least one first scribe line 31 and at least one second scribe line 32. The first scribe line 31 abuts the first device 10 in the first direction Y, that is, the first device 10 is adjacent to and contacts the at least one first scribe line 31 in the first direction Y; the second scribe line 32 abuts the first device 10 in the second direction X, that is, the first device 10 is adjacent to and contacts the at least one second scribe line 32 in the second direction X. In addition, each first scribe line 31 extends in the second direction X, and each second scribe line 32 extends in the first direction Y.

In some specific examples, TSK and MASK are placed at the first scribe lines 31 and the second scribe lines 32. It is to be noted that as shown in FIGS. 2 and 3, the size of the first scribe line 31 in the first direction Y is greater than the size of the second scribe line 32 in the second direction X such that there is an empty space in the size of the first scribe line 31 in the first direction Y. Thus, the barrier structure 20 abutting the first device 10 in the first direction Y as shown in FIG. 3 may be disposed in the empty space so as not to increase the area occupied by the first scribe lines 31. It is possible to change the floorplan layout of the wafer 1 without decreasing DPW (Dies Per Wafer). By adding the barrier structure 20 through the empty space of the first scribe line 31, the first device 10 may be secured and protected to prevent cracks occurring in the first scribe lines 31 from diffusing or extending to the first devices 10 abutting the first scribe lines 31, thereby effectively blocking extension of cracks and improving yield and reliability of effective chips.

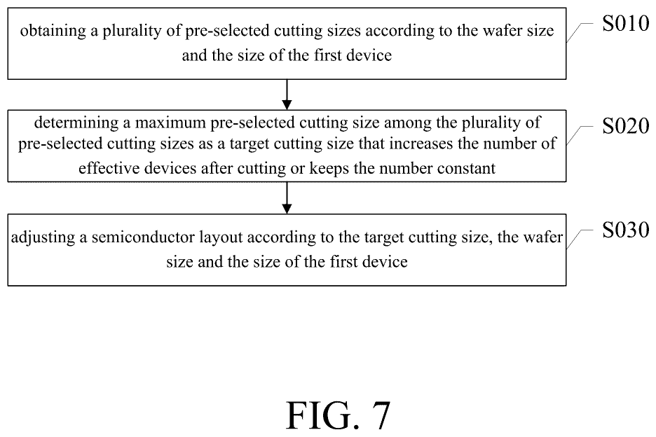

In some implementations, as shown in FIG. 7, before forming the semiconductor structures 101, the method includes the following operations:

S010, obtaining a plurality of pre-selected cutting sizes according to the wafer size and the size of the first device;

S020, determining the maximum pre-selected size among the plurality of pre-selected cutting sizes as the target cutting size that increases the number of effective devices after cutting or retains the number of effective devices; and

S030, adjusting the semiconductor layout according to the target cutting size, the wafer size and the size of the first devices.

In some specific examples, the shape of wafer 1 may include rectangle and circle, the first device 10 may include a chip or a die, and the shape of the first device includes rectangle. If the shape of the wafer 1 is circle, the wafer size may be obtained by obtaining the radius of the wafer 1, and if the shape of the wafer 1 is rectangle, the wafer size may be obtained by obtaining the length and width of the wafer 1. Similarly, the size of the first device 10 may be obtained by obtaining the length and width of the first device 10.

In an example, the pre-selected cutting size is in fact the cutting size that can satisfy the wafer size and the first device size. The pre-selected cutting size includes a first preset size of the first scribe line 31 in the first direction Y and a second preset size of the second scribe line 32 in the second direction X. While the target cutting size is a maximum pre-selected cutting size for which the number of the effective first device generated by cutting according to the plurality of pre-selected cutting sizes increases or keeps constant.

For example, the plurality of pre-selected cutting sizes includes K1, K2 and K3, and the numbers of effective first devices generated by processing according to the pre-selected cutting sizes K1, K2 and K3 are N1, N2 and N3 respectively. If N2>N1>N3, then the pre-selected cutting size K2 can be determined as the target cutting size. In implementations of the present application, it is possible to choose the pre-selected cutting size that satisfies the wafer size and the first device size from historical record data that may include information such as wafer size, chip size and scribe line size. In implementations of the present application, the corresponding pre-selected cutting size can also be designed by the engineer according to the wafer size and the first device size.

In some examples, the target cutting size is the pre-selected cutting size for which the increase of the number of effective devices after cutting is maximum or the number of the effective device keeps constant.

In some examples, to obtain the target cutting size, the pre-selected cutting size for which the increase of the number of effective device after cutting is maximum or the number of the effective device keeps constant is chosen firstly, then the maximum pre-selected cutting size is tuned to increase the preset cutting size, and if the number of effective device after tuning does not decrease or increase, then the tuned maximum pre-selected cutting size can be taken as the target cutting size.

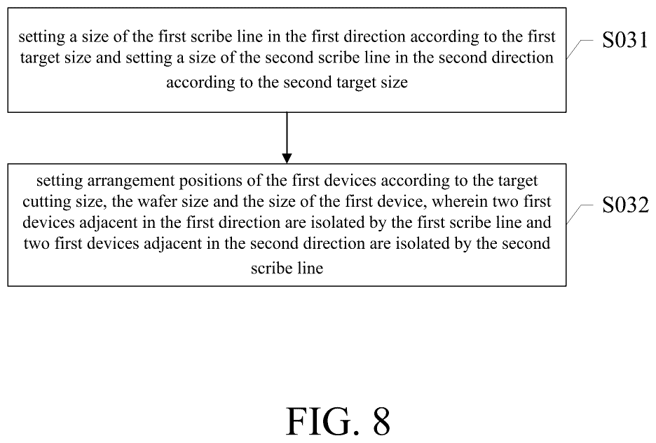

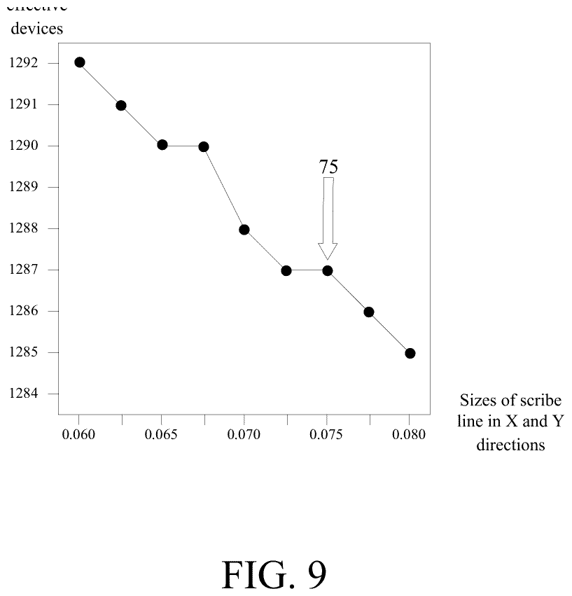

In some specific examples, as shown in FIG. 8, it is assumed that the first preset size in the first direction Y among the pre-selected cutting sizes is 60 μm to 80 μm, and the second preset size in the second direction X among the pre-selected cutting sizes is 60 μm to 80 μm.

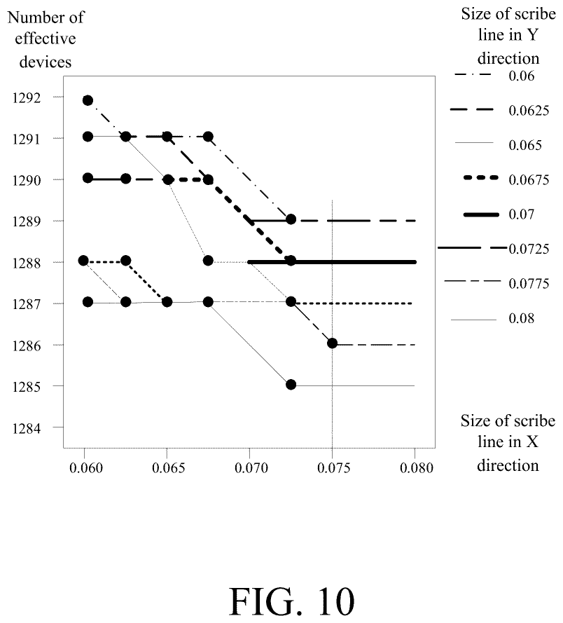

It is assumed that the second preset size in the second direction X among the pre-selected cutting sizes is 75 μm constantly. As shown in FIG. 10, the number of effective devices is substantially unchanged when the first preset size in the first direction Y among the pre-selected cutting sizes is from 72.5 μm to 80 μm. Then, a second target size among the target cutting sizes can be selected to be equal to the second preset size, i.e. 75 μm, and a first target size among the target cutting sizes can be selected to be equal to the maximum value of the first preset size in the first direction Y while the number of effective devices keeps constant, i.e. 80 μm. When the first target size is 80 μm and the second target size is 75 μm, the number of effective devices N (75,80)=1285. As compared to the number of effective devices N(75,75)=1287 when the first target size is 75 μm and the second target size is 75 μm, although the number of effective devices is reduced by a small amount, since upon cutting, the bigger the scribe line size is, the smaller the probability of cutting the first device is. And since the barrier structure 20 prevents cracks from extending to the first device 10 when cutting, which further improves the yield, the added area of the scribe line does not cause loss to the number of effective devices but drastically increases the yield of dies, thereby increasing the number of effective devices indirectly.

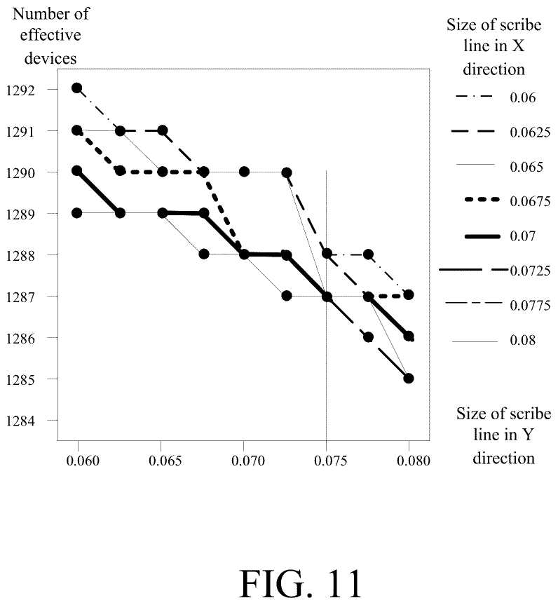

It is assumed that the first preset size in the first direction Y in the pre-selected cutting sizes is 75 μm constantly. As shown in FIG. 11, the number of effective devices is substantially unchanged when the second preset size in the second direction X among the pre-selected cutting sizes is from 72.5 μm to 80 μm. Then, the second target size in the target cutting sizes can be selected to be equal to the second preset size, i.e. 80 μm, and the first target size among the target cutting sizes can be selected to be equal to the maximum value of the first preset size in the first direction Y while the number of effective devices keeps constant, i.e. 80 μm. And when the first target size is 75 μm and the second target size is 80 μm, the number of effective devices N (80,75)=1287. As compared to the number of effective devices does not increase when the first target size is 75 μm and the second target size is 75 μm and the number of effective devices N (75,75)=1289, since upon cutting, the bigger the scribe line size is, the smaller the probability of cutting the first device is, and the greater the yield of the first device is. And since the barrier structure 20 prevents cracks from extending to the first device 10 when cutting, which further improves the yield, the added area of the scribe line does not cause loss to the number of effective devices but drastically increases the yield of dies, thereby increasing the number of effective devices indirectly.

In some implementations, the target cutting sizes include the first target size D1 in the first direction Y and the second target size D2 in the second direction X. As shown in FIG. 8, said adjusting the semiconductor layout includes:

S031, setting the size of the first scribe line 31 in the first direction Y according to the first target size and setting the size of the second scribe line 32 in the second direction X according to the second target size;

S032, setting the arrangement positions of a plurality of the first devices according to the target cutting size, the wafer size and the first device size, wherein two first devices 10 adjacent in the first direction Y are isolated by the first scribe line 31 and the two first devices 10 adjacent in the second direction X are isolated by the second scribe line 32.

In some specific examples, the target cutting sizes include the first target size D1 in the first direction Y and the second target size D2 in the second direction X. Thus, as shown in FIGS. 2 and 3, the first target size is set as the size of the first scribe line 31 in the first direction Y, and the second target size is set as the size of the second scribe line 32 in the second direction X. Then, the arrangement positions of a plurality of the first devices 10 on the wafer 1 are set according to the target cutting size, the wafer size and the first device size, such that two first devices 10 adjacent in the first direction Y are isolated by the first scribe line 31 and the two first devices 10 adjacent in the second direction X are isolated by the second scribe line 32.

In the present application, since when cutting wafer 1, the greater the size of the first scribe line 31 in the first direction Y and the size of the second scribe line 32 in the second direction X are, the smaller the probability of cutting the first device 10 is and the greater the yield of chips obtained by cutting wafer 1 is, then by way of adjusting sizes of scribe lines 30 in the semiconductor layout that is, increasing sizes of all or part of the scribe lines, e.g., increasing sizes of all or part of first scribe lines 31 in the first direction Y or increasing sizes of all or part of second scribe lines 32 in the second direction X, it is possible to increase the number of effective chips produced by cutting wafer 1, reduce the waste of wafer 1 and save production costs of chips, without changing the value of DPW (Dies Per Wafer, number of cuttable wafers 1 or number of chips cuttable from wafer).

In some implementations, the size AD of the barrier structure 20 in the first direction Y is equal to a half of the difference between the first target size D1 of the first scribe line 31 in the first direction Y and the preset cutting size L1 that is equal to the second target size D2 of the second scribe line 32 in the second direction X.

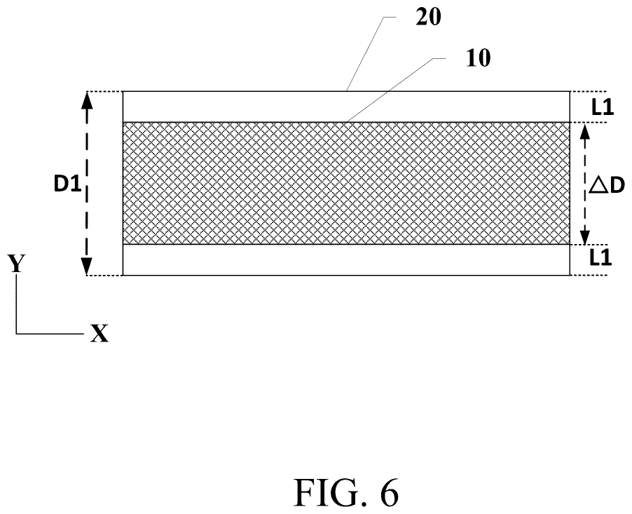

In some specific examples, as shown in FIGS. 3 and 6, the size of the barrier structure 20 in the first direction Y is

$$Δ D = \frac{1}{2} ( D 1 - L 1 ) = \frac{1}{2} ( D 1 - D 2 ) ,$$

wherein L1 is the second target size D2 of the second scribe line 32 in the second direction X.

In some specific examples, as a continuation of the above-described implementation, it is assumed that when the first target size, i.e. the first target size D1 of the first scribe line 31 in the first direction Y is 80 μm, and the second target size, i.e. the second target size D2 of the second scribe line 32 in the second direction X is 75 μm, the size of the barrier structure in the first direction Y is

$$Δ D = \frac{1}{2} ( D 1 - D 2 ) = \frac{1}{2} ( 80 - 75 ) = 2.5 um .$$

In some implementations, the wafer 1 includes any one of an array wafer, a CMOS wafer, a carrier wafer and a device wafer.

The target cutting size is selected in the present application such that not only the number of effective devices after cutting has a greatest increase or keeps constant, but also it is the maximum pre-selected cutting size among the plurality of pre-selected cutting sizes. Thus, when the number of effective devices is not changed or even the number of effective devices is increased, it is possible to reduce the probability of cutting first device 10 in the cutting process by cutting chips via scribe lines 30 with increased sizes, which in turn increases the yield. Also, it is possible to add the barrier structure 20 in the empty area of the first scribe line 31 with increased size by which it is possible to prevent cracks occurring in the first scribe line 31 from diffusing or extending to the first device 10 abutting the first scribe line 31, thereby effectively blocking extension of cracks and improving the yield and reliability of chips.

An implementation of the present application further provides a semiconductor device 100 including:
a wafer 1 including a plurality of semiconductor structures 101 each of which including a first device 10 and a first scribe line 31 abutting the first device 10 in a first direction Y and extending in a second direction X, the first direction Y intersecting the second direction X; and
a barrier structure 20 extending in the second direction X and located at a site in the first scribe line 31 abutting the first device 10.

In some implementations, the barrier structure 20 includes a plurality of grooves 21 arranged at intervals in the second direction X and extending in the first direction Y.

In some implementations, the semiconductor structure 101 further includes a second scribe lines 32 abutting the first device 10 in the second direction X and extending in the first direction Y;
wherein the size of the first scribe line 31 in the first direction Y is greater than the size of the second scribe line 32 in the second direction X.

In some implementations, the size AD of the barrier structure 20 in the first direction Y is equal to a half of the difference between a first target size D1 of the first scribe line 31 in the first direction Y and a preset cutting size L1 that is equal to a second target size D2 of the second scribe line 32 in the second direction X.

In some implementations, the wafer 1 includes any one of an array wafer, a CMOS wafer, a carrier wafer and a device wafer.

The semiconductor device 100 in the implementation of the present application is fabricated with the above-described fabrication method of semiconductor device 100. Therefore, corresponding implementations of the above S100 to S200 are referred to for detail description of the structures and effects of the semiconductor device 100 in implementations of the present application, which will not be described in detail again.

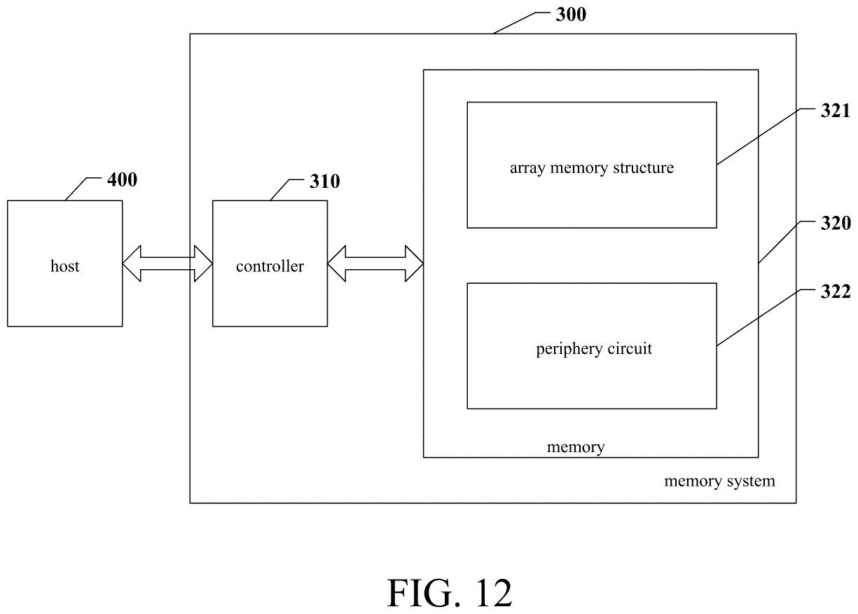

Based on the above-described semiconductor device 100 and the fabrication method thereof, referring to FIG. 12, an implementation of the present application further provides a memory 320 including:
an array memory structure 321 including a semiconductor device 100 as shown in the implementation of FIGS. 2 to 6; and
a peripheral circuit 322 connected with the array memory structure 321 to control the bias voltage of the array memory structure 321.

Based on the above-described semiconductor device 100 and the fabrication method thereof, referring to FIG. 12, an implementation of the present application further provides a memory system 300 including a memory 320 and a controller coupled with the memory 320, wherein the memory includes a semiconductor device 100 as described in implementations corresponding to FIGS. 2 to 6 and the controller is configured to control the memory to execute data writing and reading operations.

Specifically, as shown in FIG. 12, a memory system 300 includes a controller 310 and one or more memories 320, wherein the memory 320 (3D NAND Flash) includes an array memory structures 321 (Array) and a peripheral circuit 322, and wherein the array memory structure 321 includes a semiconductor device 100 of any one of the above-described items. The memory system 300 may communicate with a host 400 through the controller 310, which may in turn be connected to the one or more memories 320 through pathways therein. Each memory 320 may be controlled by the controller 310 through the pathway in the memory 320.

In an example, the array memory structure 321 is configured to store information, the peripheral circuit 322 may be above or below, or on the periphery of, the array memory structure 321, and is configured to control the corresponding array memory structure 321. Moreover, the semiconductor device 100 may be applied in other microelectronic device, such as, but not limited to, non-volatile flashes (NOR flashes). Furthermore, the semiconductor device 100 in implementations of the present application may be a memory 320 or a part of a periphery memory, which is not limited specifically.

The present application provides a semiconductor device and a fabrication method thereof, and a memory system, which can increase production of chips and reduce costs of fabrication.

The present application provides a fabrication method of a semiconductor device including:
forming a semiconductor structure in a wafer, comprising forming a first device and a first scribe line abutting the first device in a first direction and extending in a second direction, the first direction intersecting the second direction; and
forming a barrier structure extending in the second direction at a site in the first scribe line abutting the first device.

In a second aspect, the present application further provides a semiconductor device, including:
a wafer including a plurality of semiconductor structures each of which including a first device and a first scribe line abutting the first device in a first direction and extending in a second direction, the first direction intersecting the second direction; and
a barrier structure extending in the second direction and located at a site in the first scribe line abutting the first device.

In a third aspect, the present application also provides a memory system that includes a controller and a three-dimensional memory, wherein the controller is coupled to the three-dimensional memory and configured to control the three-dimensional memory to store data, and the three-dimensional memory includes the semiconductor device of the second aspect.

In the present application, barrier structures disposed at intervals are formed between the first devices adjacent in the first direction by utilizing the existing empty spaces in the first scribe line such that it is possible to prevent cracks from diffusing to the first device, thereby effectively blocking extension of cracks, improving chip yield and reliability, improving productions of chips and reducing costs of fabrication.

The semiconductor device 100 and the fabrication method thereof, the memory and the memory system 300 provided in implementations of the present application have been described in detail above. Specific examples are used herein to set forth the principle and implementations of the present application and description of the above implementations is only for assisting understanding the method and gist thereof of the present application. Meanwhile, those skilled in the art may make modifications to implementations and ranges according to the idea of the present application. In summary, the contents of the present specification should not be construed as limiting the present application.

What is claimed is:

1. A fabrication method of a semiconductor device, comprising:
forming a semiconductor structure in a wafer, comprising forming a first device and a first scribe line abutting the first device in a first direction and extending in a second direction, the first direction intersecting the second direction; and
forming a barrier structure extending in the second direction at a site in the first scribe line abutting the first device.

2. The method of claim 1, wherein forming the barrier structure extending in the second direction further comprises:
forming a plurality of ring shape structures extending in the second direction in the first scribe line; and
forming a plurality of grooves arranged at intervals in the second direction in the ring shape structures, the grooves extending in the first direction.

3. The method of claim 1, wherein forming the semiconductor structure comprises forming a second scribe line abutting the first device in the second direction and extending in the first direction, and a size of the first scribe line in the first direction is greater than a size of the second scribe line in the second direction.

4. The method of claim 3, wherein before forming the semiconductor structure, the method further comprises:
obtaining a plurality of pre-selected cutting sizes according to a wafer size and a size of the first device;
determining a maximum pre-selected cutting size among the plurality of pre-selected cutting sizes as a target cutting size that increases a number of effective devices after cutting or retains the number of effective devices; and
adjusting a semiconductor layout according to the target cutting size, the wafer size and the size of the first device.

5. The method of claim 4, wherein the target cutting sizes comprise a first target size in the first direction and a second target size in the second direction, and the adjusting the semiconductor layout comprises:
setting a size of the first scribe line in the first direction according to the first target size and setting a size of the second scribe line in the second direction according to the second target size; and
setting arrangement positions of a plurality of the first devices according to the target cutting size, the wafer size and the size of the first devices, wherein two first devices adjacent in the first direction are isolated by the first scribe line and the two first devices adjacent in the second direction are isolated by the second scribe line.

6. The method of claim 5, wherein a size of the barrier structure in the first direction is equal to a half of a difference between the first target size of the first scribe line in the first direction and a preset cutting size that is equal to the second target size of the second scribe line in the second direction.

7. The method of claim 1, wherein the wafer comprises any one of an array wafer, a CMOS wafer, a carrier wafer and a device wafer.

8. A semiconductor device, comprising:
a wafer including a plurality of semiconductor structures each of which including a first device and a first scribe line abutting the first device in a first direction and extending in a second direction, the first direction intersecting the second direction; and
a barrier structure extending in the second direction and located at a site in the first scribe line abutting the first device.

9. The semiconductor device of claim 8, wherein the barrier structure comprises a plurality of grooves arranged at intervals in the second direction and extending in the first direction.

10. The semiconductor device of claim 9, wherein the semiconductor structure further comprises a second scribe line abutting the first device in the second direction and extending in the first direction, wherein a size of the first scribe line in the first direction is greater than a size of the second scribe line in the second direction.

11. The semiconductor device of claim 10, wherein a size of the barrier structure in the first direction is equal to a half of a difference between a first target size of the first scribe line in the first direction and a preset cutting size that is equal to a second target size of the second scribe line in the second direction.

12. The semiconductor device of claim 8, wherein the wafer comprises any one of an array wafer, a CMOS wafer, a carrier wafer and a device wafer.

13. A memory system, comprising:
a three-dimensional memory, the three-dimensional memory comprising a semiconductor device comprising:
a wafer including a plurality of semiconductor structures each of which including a first device and a first scribe line abutting the first device in a first direction and extending in a second direction, the first direction intersecting the second direction; and
a barrier structure extending in the second direction and located at a site in the first scribe line abutting the first device,
a controller that is coupled to the three-dimensional memory and configured to control the three-dimensional memory to store data.
